(19) United States
(12) Patent Application Publication
(10) Pub. No.: US 2025/0349666 A1
(43) Pub. Date: Nov. 13, 2025

(54) SEMICONDUCTOR PACKAGE WITH HEAT SPREADING LID

(71) Applicant: Taiwan Semiconductor Manufacturing Company, Ltd., Hsinchu (TW)

(72) Inventors: WENSEN HUNG, ZHUBEI (TW); YEN-PU CHEN, HSINCHU (TW); WEI-KONG SHENG, CHU-NAN (TW); TSUNG-YU CHEN, HSINCHU (TW)

(21) Appl. No.: 18/659,745

(22) Filed: May 9, 2024

(51) Int. Cl. H01L 23/42; H01L 23/00; H01L 23/367; H01L 23/38; H01L 23/538; H01L 25/00; H01L 25/065

(52) U.S. Cl. CPC H01L 23/42; H01L 23/367; H01L 23/38; H01L 23/5383; H01L 23/562; H01L 24/29; H01L 24/32; H01L 24/83; H01L 25/0655; H01L 25/50; H01L 2224/29109; H01L 2224/29139; H01L 2224/29147; H01L 2224/2929; H01L 2224/29305; H01L 2224/32225; H01L 2224/83493; H01L 2224/8385

(57) ABSTRACT

A semiconductor package includes an interposer having a first principle surface and a second principle surface opposite the first principle surface. One or more semiconductor dies are disposed on the first principle surface of the interposer, and are electrically connected with the second principle surface of the interposer by electrical vias passing through the interposer. A heat spreading lid disposed over the one or more semiconductor dies. A thermally conductive material is disposed between the one or more semiconductor dies and the heat spreading lid. The thermally conductive material thermally couples the one or more semiconductor dies and the heat spreading lid. In some examples, the heat spreading lid may be a thermoelectric cooler. In some examples, the thermally conductive material may be a mixture of a gel and a liquid metal.

### BACKGROUND

The following relates to semiconductor packages, to semiconductor packages with integrated heat spreading and/or cooling, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates an exploded sectional view of a semiconductor package including a thermoelectric cooler that is thermally coupled with semiconductor dies by a thermal interface material.

FIG. 2 diagrammatically illustrates a sectional view of the semiconductor package of FIG. 1.

FIG. 3 diagrammatically illustrates a bottom view of the thermoelectric cooler of the semiconductor package of FIGS. 1 and 2.

FIG. 4 diagrammatically illustrates an exploded sectional view of a semiconductor package including a thermoelectric cooler that is thermally coupled with semiconductor dies by a liquid metal.

FIG. 5 diagrammatically illustrates an exploded sectional view of a semiconductor package including a high-thermal conductivity lid that is thermally coupled with semiconductor dies by a liquid metal.

FIG. 6 shows a flowchart of a method of assembling a semiconductor package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor assembly or package includes one or more semiconductor dies such as integrated circuit (IC) chips fabricated on/in silicon, which are mounted on a first (e.g., top) principle surface of an interposer, which in turn is disposed on a substrate, such as a printed circuit board (PCB). The interposer may, for example, comprise a silicon wafer with through vias providing electrical communication from the first principle surface on which the one or more semiconductor dies are mounted to an opposite second (e.g., bottom) principle surface which contacts the substrate. The interposer may optionally include a redistribution layer (RDL) to provide complex electrical routing of electrical signals and/or power between the first and second principle sides of the interposer. The combination of the one or more semiconductor dies mounted on the interposer may be mounted on the substrate. While the forgoing are referenced here as illustrative examples, approaches for thermal management disclosed herein are also applicable to other types of semiconductor packages that may be referred to by different nomenclatures, such as three-dimensional integrated circuit packages.

Thermal management is a challenge in semiconductor packages. A goal of some package designs is to reduce the package footprint by close placement of multiple semiconductor dies (some or all of which may be high-power IC chips) on the interposer, thus forming a concentrated high power heat source. Cooling can be provided through the interposer to the underlying substrate, but this heat dissipation pathway is limited by the thermal conductivity of the ball grid arrays (BGAs) and underfill materials forming the interfaces between the semiconductor dies and the interposer and between the interposer and the substrate, as well as by the thermal resistance presented by the interposer itself. To provide further cooling, a cold plate or heat sink can be disposed on top of the one or more semiconductor dies. However, total power consumption and power density continually increases with advancement of semiconductor die and package designs, such as advanced central processing unit (CPU) and graphical processing unit (GPU) packages for high performance computing (HPC) and artificial intelligence (AI) applications. In some nonlimiting illustrative examples, commercial CPU or GPU packages can have hot spots with maximum power density of around 4 W/mm², and total chip power of around 400-600 watts or higher.

Disclosed herein are semiconductor chip packages, and corresponding methods of assembling semiconductor packages, with improved thermal management. In some illustrative embodiments, a semiconductor package includes one or more semiconductor dies disposed on a first principle surface of an interposer and electrically connected with an opposite second principle surface of the interposer by electrical vias passing through the interposer. A heat spreading lid is disposed over the one or more semiconductor dies. Thermally conductive material is disposed between the one or more semiconductor dies and the heat spreading lid, which thermally couples the one or more semiconductor dies and the heat spreading lid. A cold plate or heat sink is disposed on the heat spreading lid. In some embodiments, the heat spreading lid comprises a thermoelectric cooler, while in other embodiments the heat spreading lid comprises a metal, a single-crystal diamond, or a combination thereof (e.g., a higher thermal conductivity single-crystal diamond layer proximate to the one or more semiconductor dies, and a lower thermal conductivity metal layer distal from the one or more semiconductor dies). The thermally conductive material may comprise a thermally conductive metal or metal alloy such as indium, silver, copper, an indium alloy, a silver alloy, a copper alloy, or a solder material. In other embodiments, the thermally conductive material may comprise a mixture of a gel and a liquid metal, such as a mixture of a polymer gel and a liquid metal such as gallium having a melting temperature that is sufficiently low so that the liquid metal is in its liquid phase at the design-basis operating temperature of the semiconductor package. The semiconductor package may further include a stiffener ring disposed on the first principle surface of the interposer and encircling the one or more semiconductor dies, a molding material molded around the stiffener ring and the one or more semiconductor dies. In embodiments in which the thermally conductive material may comprise a mixture of a gel and a liquid metal, an adhesive may be disposed on a periphery of the heat spreading lid, which contains the mixture of the gel and the liquid metal when the metal liquefies at package operating temperature. The adhesive may also bond the thermoelectric cooler to the molding material.

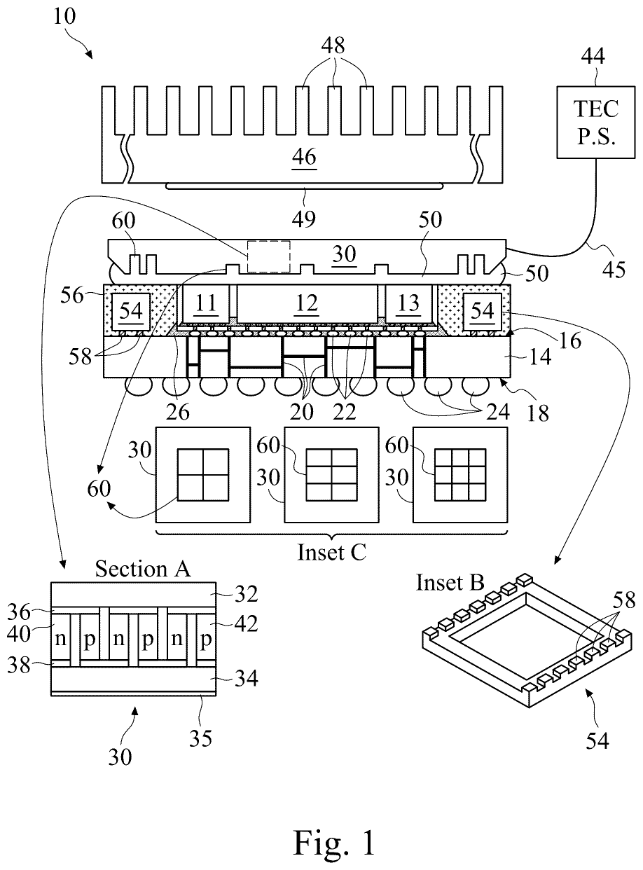

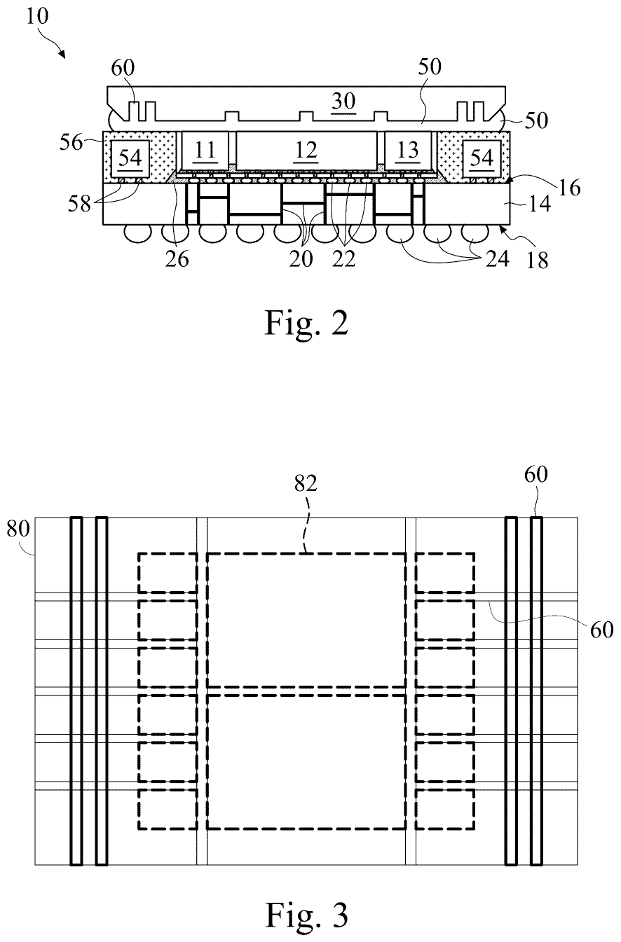

With reference now to FIGS. 1 and 2, a semiconductor package 10 according to one nonlimiting illustrative embodiment is described. FIG. 1 diagrammatically illustrates an exploded sectional view of the semiconductor package 10, while FIG. 2 diagrammatically illustrates a sectional view of the semiconductor package 10. The semiconductor package 10 includes one or more (illustrative three) semiconductor dies 11, 12, 13 disposed on an interposer 14. More particularly, the one or more semiconductor dies 11, 12, 13 are disposed on a first (e.g., upper or top) principle surface 16 of the interposer 14. An opposite second (e.g., lower, or bottom) principle surface 18 of the interposer 14 is on an opposite side of the interposer 14 from the first principle surface 16. The one or more semiconductor dies 11, 12, 13 disposed on the first principle surface 16 of the interposer 14 are electrically connected with the second principle surface 18 of the interposer 14 by electrical vias 20 that pass through the interposer 14. More particularly, in the illustrative example of FIGS. 1 and 2 a first set of bonding bumps 22 disposed on the first principle surface 16 of the interposer 14 provide electrical connection between contact pads (not shown) of the one or more semiconductor dies 11, 12, 13 and ends of the electrical vias 20 at the first principle surface 16. A second set of bonding bumps 24 are disposed on the second principle surface 18 of the interposer 14 and electrically connect with ends of the electrical vias 20 at the second principle surface 18. The first set of bonding bumps 22 may be microballs, and may form a ball grid array (BGA) aligned with contact pads of the one or more semiconductor dies 11, 12, 13. The first set of bonding bumps 22 also typically provide or contribute to mechanical attachment of the one or more semiconductor dies 11, 12, 13 to the first principle surface 16 of the interposer 14. In some embodiments, underfill material 26 fills the space between the bonding bumps 22, the first principle surface 16 of the interposer 14, and the proximate surfaces of the one or more semiconductor dies 11, 12, 13. The second set of bonding bumps 24 may, for example, form a BGA for bonding the semiconductor package 10 to aligned pads of a printed circuit board (PCB) or other substrate (not shown). The bonding bumps 22 and 24 may comprise solder bumps, solder-coated copper balls, or other suitable electrically conductive bumps.

The one or more semiconductor dies 11, 12, 13 may in general include any type of semiconductor die or combination of types of semiconductor dies. By way of some nonlimiting examples, the one or more semiconductor dies 11, 12, 13 may include integrated circuit (IC) dies such as microprocessors, microcontrollers, CPU dies, GPU dies, solid-state memory dies, application-specific integrated circuits (ASICs), field-programmable gate arrays (FPGAs), photonic dies (e.g., semiconductor LEDs, lasers, photodetectors, and/or so forth), various combinations thereof, and/or so forth. These are merely some nonlimiting illustrative examples. The one or more semiconductor dies 11, 12, 13 may be silicon or silicon-based dies, or group III-V semiconductor dies, silicon germanium and/or silicon carbide dies, various combinations thereof, or so forth. While each of the semiconductor dies 11, 12, 13 are illustrated as a single die, it is also contemplated for a given semiconductor die (for example, the semiconductor die 12) to be a stack of two (or more) semiconductor dies.

The interposer 14 is typically a silicon interposer, although a sapphire interposer, a silicon carbide interposer, or other-material interposer is also contemplated. The electrical vias 20 passing through the interposer 14 may, for example, include through-silicon vias (TSV) that pass through the (in this case silicon) interposer 14, and/or the electrical vias 20 may include a redistribution layer (RDL, not shown) at one or both of the first and second principle surfaces 16, 18 of the interposer 14. Inclusion of an RDL provides electrical pathways for redistributing electrical signals and/or power passing between the one or more semiconductor dies 11, 12, 13 and the second set of bonding bumps 24.

To provide thermal management, e.g., cooling, for the one or more semiconductor dies 11, 12, 13, a heat spreading lid in the form of a thermoelectric cooler 30 is disposed over the one or more semiconductor dies 11, 12, 13. As diagrammatically shown in a Section A view shown in FIG. 1, the thermoelectric cooler 30 may be constructed as a Peltier cooling device, including a first thermally conducting plate 32, a second thermally conducting plate 34 (with optional backside metal coating 35), first electrical connections 36 disposed on the first thermally conducting plate 32, second electrical connections 38 disposed on the second thermally conducting plate 34, and n-type regions 40 and p-type regions 42 disposed between the thermally conducting plates 32 and 34 and electrically connected with the electrical connections 36 and 38. The thermally conducting plates 32 and 34 are thermally conductive but electrically insulating, and may, for example, comprise ceramic plates such as ceramic beryllia (BeO) plates. Hence, the n-type regions 40 and p-type regions 42 are thermally connected in parallel between the thermally conducting plates 32 and 34. On the other hand, as seen in Section A, the n-type regions 40 and p-type regions 42 are electrically connected in series by the electrical connections 36 and 38 to form . . . n/p/n/p/ . . . series-connected junctions. In response to an electrical current flowing through the series-connected n-type regions 40 and p-type regions 42, e.g. driven by a thermoelectric cooler (TEC) power supply (P.S.) 44 connected to the thermoelectric cooler 30 by wires 45, heat transfers from the hot side corresponding to the second thermally conductive plate 34 which is in thermal contact with the one or more semiconductor dies 11, 12, 13, to the cold side corresponding to the first thermally conductive plate 32 which is in thermal contact with a cold plate or heat sink 46 that is disposed on the heat spreading thermoelectric cooler 30 (see main drawing of FIG. 1; note the cold plate or heat sink is not shown in FIG. 2). This heat transfer operates by the Peltier effect to actively transfer heat from the one or more semiconductor dies 11, 12, 13 to the cold plate or heat sink 46. The thermoelectric cooler 30 can have various thicknesses. In some nonlimiting illustrative examples, the thermoelectric cooler 30 has a thickness of about 1-5 millimeters or thicker.

In the illustrative embodiment shown in FIG. 1, the illustrative thermoelectric cooler power supply 44 provides operating power for the thermoelectric cooler 30. However, in a variant embodiment (not shown), the thermoelectric cooler power supply may be integrated into the one or more semiconductor dies 11, 12, 13, for example implemented as a DC power supply circuit implemented as an integrated circuit (IC) of the one or more semiconductor dies 11, 12, 13. In such embodiments, the wires 45 are suitably implemented as insulated electrical feedthroughs (not shown) that connect with the thermoelectric cooler 30.

The cold plate or heat sink 46 may be variously constructed. In some embodiments, the cold plate or heat sink 46 may be a passive cooling component such as a metal plate or slab with suitably large heat capacity to absorb and dissipate the heat generated by the one or more semiconductor dies 11, 12, 13 and transferred to the cold plate or heat sink 46 by action of the thermoelectric cooler 30. In other embodiments, cold plate or heat sink 46 may implement active cooling, such as including a cooling fan, including fluid (e.g., air or water) conduits (which may optionally have positive fluid flow supplied by piping or tubing and driven by a cooling pump, optional components not shown). The illustrative cold plate or heat sink 46 includes optional thermal dissipation fins 48 that increase its surface area to promote heat transfer to the ambient (e.g., air). Additionally, as shown in FIG. 1 a thermal interface material 49 coats the opposite surface of the cold plate or heat sink 46 which contacts the thermoelectric cooler 30 to improve heat transfer from the thermoelectric cooler 30 to the cold plate or heat sink 46. The thermal interface material 49 may, by way of some nonlimiting illustrative examples, comprise indium, silver, copper, an indium alloy, a silver alloy, a copper alloy, or a solder material. In some nonlimiting illustrative embodiments the thermal interface material 49 has a thickness of 200 microns or less, and in some such embodiments is in a range of 50-100 micron.

To provide a thermally conductive coupling between the thermoelectric cooler 30 and the one or more semiconductor dies 11, 12, 13, the thermally conductive plate 34 (see Section A) of the thermoelectric cooler 30 proximate to the one or more semiconductor dies 11, 12, 13 may optionally include the backside metal coating 35. In one nonlimiting illustrative example, the backside metal coating 35 may be a titanium/copper/NiV/gold stack (where NiV is a nickel-vanadium alloy), with the titanium closest to the one or more semiconductor dies 11, 12, 13 and the gold in contact with the thermally conductive plate 34. In one nonlimiting illustrative example, the NiV may have a thickness of about 3500 angstroms, and the gold may have a thickness of about 1000 angstroms. Additionally or alternatively, thermally conductive material may be disposed between the one or more semiconductor dies and the thermoelectric cooler 30 to thermally couple the one or more semiconductor dies 11, 12, 13 and the thermoelectric cooler 30. In the semiconductor package 10 of FIGS. 1 and 2, the thermally conductive material is a thermal interface material 50 that is disposed between the one or more semiconductor dies 11, 12, 13 and the thermoelectric cooler 30 that forms the heat spreading lid of the semiconductor package 10 of FIGS. 1 and 2. The thermal interface material 50 is thermally conductive and sufficiently mechanically deformable under pressure to deform to a shape that conforms with the mutually facing surfaces of the thermoelectric cooler 30 and the one or more semiconductor dies 11, 12, 13, thereby increasing the contact area for thermal transfer. The thermal interface material 50 may, by way of some nonlimiting illustrative examples, comprise indium, silver, copper, an indium alloy, a silver alloy, a copper alloy, or a solder material. The thickness of the thermal interface material 50 can vary depending on factors such as the material type, the geometry of the one or more semiconductor dies 11, 12, 13 and the facing surface of the thermoelectric cooler 30, and so forth. In some nonlimiting illustrative embodiments the thermal interface material 50 has a thickness of 200 microns or less, and in some such embodiments is in a range of 50-100 micron.

To improve structural robustness of the semiconductor package 10, an optional stiffener ring 54 is disposed on the first principle surface 16 of the interposer 14. The stiffener ring 54 encircles the one or more semiconductor dies 11, 12, 13. A molding material 56 is molded around the stiffener ring 54 and the one or more semiconductor dies 11, 12, 13. The stiffener ring 54 is shown in side section in the main drawing of FIG. 1 and in FIG. 2; an Inset B isolation perspective view of the stiffener ring 54 also included in FIG. 1 illustrates the stiffener ring 54 has a rectangular shape, and includes optional pedestals or feet 58 on which the stiffener ring 54 is supported on the first principle surface 16 of the interposer 14. In FIG. 1, Inset B the optional pedestals or feet 58 are disposed on two opposite sides of the four sides of the illustrative stiffener ring 54; however, in other embodiments the pedestals or feet may be included on all four sides of the stiffener ring. The pedestals or feet 58, if provided, facilitate the molding material 56 flowing underneath the stiffener ring 54 to encapsulate it. The stiffener ring 54 is suitably made of a stiff material to provide the desired stiffening of the overall semiconductor package 10. In some nonlimiting illustrative examples, the stiffener ring 54 may have a coefficient of thermal expansion in a range of 3-10 ppm/° C., although values outside this range are also contemplated. In some embodiments, the stiffener ring 54 may have an elastic modulus of 60-380 GPa, although values outside this range are also contemplated. In some nonlimiting illustrative examples, the stiffener ring 54 may comprise copper, a nickel-iron alloy such as alloy-42, a stainless steel such as SUS420, nickel, tungsten, copper-tungsten, copper-molybdenum, invar, or so forth.

As seen in the main drawing of FIG. 1 and in FIG. 2, the molding 56 has an upper surface (i.e., surface distal from the interposer 14) which is approximately coplanar with the upper surface (i.e., surface distal from the interposer 14) of the one or more semiconductor dies 11, 12, 13.

In some embodiments, the thermoelectric cooler 30 has grooves 60 formed in the surface of the thermoelectric cooler 30 facing the one or more semiconductor dies 11, 12, 13 and the stiffener ring 54. The thermal interface material 50 fills the grooves 60 of the thermoelectric cooler 30. The optional grooves 60 provide paths for outgassing during compressive placement of the thermoelectric cooler 30 on the thermal interface material 50. The filling of the grooves 60 with the thermal interface material 50 also improves thermal conduction of heat from the one or more semiconductor dies 11, 12, 13 through the thermal interface material 50 to the thermoelectric cooler 30. The grooves 60 can have various geometries, as diagrammatically shown in Inset C included in FIG. 1. Inset C shows bottom views of the thermoelectric cooler 30 with three different pattern embodiments for the grooves 60. These patterns are merely nonlimiting illustrative examples. The grooves 60 may in some embodiments have depths in a range of 0.1 millimeter to 0.5 millimeter, and widths in a range of 0.5 millimeter to 2 millimeter, although values outside these dimensional ranges are also contemplated.

With reference to FIG. 3, a diagrammatic projection view is shown of certain features of the semiconductor package 10, showing the relative positions of the layouts of these certain features. The certain features diagrammatically indicated in FIG. 3 include an area 80 of the interposer 14, a die projection area 82 of the one or more semiconductor dies 11, 12, 13 (shown using a dashed line), and a nonlimiting illustrative layout of the grooves 60 of the thermoelectric cooler 30. FIG. 3 is to be understood as showing one nonlimiting illustrative layout of the semiconductor package 10, and other layouts are contemplated for each of the die projection area and the grooves.

As previously mentioned, in the embodiment of FIGS. 1 and 2 the thermally conductive material disposed between the one or more semiconductor dies 11, 12, 13 and the heat spreading lid (implemented in FIGS. 1 and 2 as the thermoelectric cooler 30) is a thermal interface material 50, such as (by way of nonlimiting illustrative example) indium, silver, copper, an indium alloy, a silver alloy, a copper alloy, or a solder material.

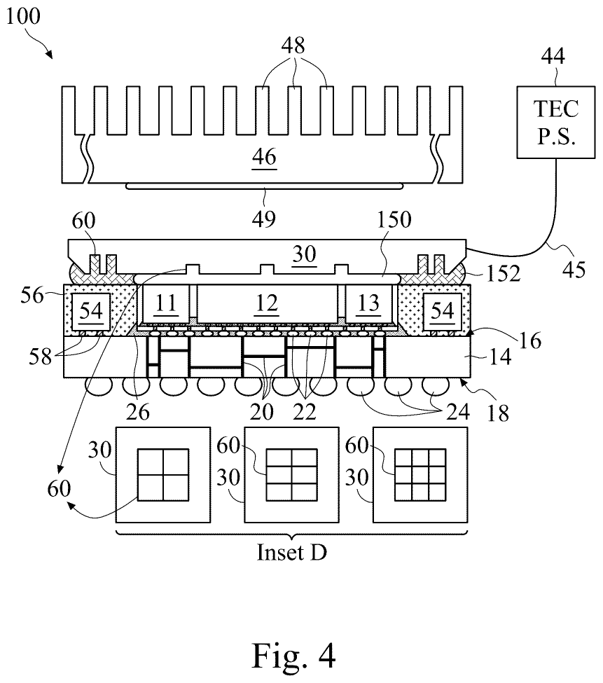

With reference to FIG. 4, an exploded sectional view is shown of a semiconductor package 100 according to another embodiment, which again employs the thermoelectric cooler 30 with grooves 60 as the heat spreading lid, e.g., constructed as a Peltier device as described with reference to Section A shown in FIG. 1. The semiconductor package 100 also includes many other components which are the same as already described for the semiconductor package 10 of FIGS. 1 and 2, including: the one or more semiconductor dies 11, 12, 13; the interposer 14 with first and second principle surfaces 16 and 18 and electrical vias 20 passing therethrough; sets of bonding bumps 22 and 24 and underfill material 26 filling the space between the bonding bumps 22; thermoelectric cooler (TEC) power supply (P.S.) 44 and connecting wires 45 (or, as previously described, if the power supply for the thermoelectric cooler 30 is integrated with the one or more semiconductor dies 11, 12, 13 then the wires 45 can be replaced by suitable insulated electrical feedthroughs connecting the one or more semiconductor dies 11, 12, 13 and the thermoelectric cooler 30); the cold plate or heat sink 46 with optional thermal dissipation fins 48 and thermal interface material 49 coating the surface which contacts the thermoelectric cooler 30; and the stiffener ring 54 with optional pedestals or feet 58 and surrounding molding material 56.

However, the semiconductor package 100 of FIG. 4 differs from the semiconductor package 10 of FIGS. 1 and 2 in that the semiconductor package 100 of FIG. 4 has a different type of thermally conductive material disposed between the one or more semiconductor dies 11, 12, 13 and the thermoelectric cooler 30 which serves as the heat spreading lid. In the semiconductor package 100 of FIG. 4, the thermally conductive material disposed between the one or more semiconductor dies 11, 12, 13 and the thermoelectric cooler 30 is a mixture 150 of a gel and a liquid metal. In some nonlimiting illustrative embodiments, the liquid metal comprises gallium, which has a melting point of about 30° C., and the gel comprises a polymer. As the melting point of gallium is slightly above room temperature (typically taken as around 20° C. to 24° C.) and is below the typical design-basis operating temperature of the semiconductor package 100, the gallium is in its liquid phase at the operating temperature of the semiconductor package 100. This liquefication facilitates the liquid gallium being in intimate thermal contact with the one or more semiconductor dies 11, 12, 13 and the thermoelectric cooler 30 to efficiently transfer heat from the one or more semiconductor dies 11, 12, 13 to the thermoelectric cooler 30. While gallium is a suitable liquid metal for use in the mixture 150 of gel and liquid metal, other suitable metals that are liquid at the operating temperature of the semiconductor package 100 are contemplated as the liquid metal of the mixture 150. In a nonlimiting illustrative example, the mixture 150 of gel and liquid metal may have a thickness of about 100 micron or less. In some embodiments the thickness of the mixture 150 of gel and liquid metal may be nonuniform, e.g. with a thickness of about 30 micron or less in the center and about 100 microns or more at the periphery. These are merely nonlimiting illustrative examples.

In the semiconductor package 10 of FIG. 1, the thermal interface material 50 is typically solid at the operating temperature of the semiconductor package 10, and so as seen in FIGS. 1 and 2 the thermal interface material 50 suitably extends over the stiffener ring 54 (or more specifically over the molding 56 that coats the stiffener ring 54). By contrast, the semiconductor package 100 employs the mixture 150 of gel and liquid metal as the thermally conductive material disposed between the one or more semiconductor dies 11, 12, 13 and the heat spreading lid. As the metal (e.g., gallium) is in its liquid phase at the operating temperature of the semiconductor package 100, the semiconductor package 100 of FIG. 4 includes an adhesive 152 disposed on a periphery of the thermoelectric cooler 30, e.g. on the molding 56 surrounding the stiffening ring 54. The adhesive 152 encircles and contains the mixture 150 of gel and liquid metal so that the liquefied metal (e.g., liquid gallium) does not flow and escape from the semiconductor package 100 at its operating temperature. The adhesive 152 may comprise elastomer adhesive, sealant adhesive, thermal paste, or so forth.

As seen in FIG. 4, the adhesive 152 also fills the peripheral grooves 60 of the surface of the thermoelectric cooler 30, thus further facilitating containment of the mixture 150 of gel and liquid metal. In some nonlimiting implementations, the adhesive 152 may fill the grooves 60 at a liquid phase when initially applied, but becomes solid after curing and/or during package operation. Meanwhile, the mixture 150 of gel and liquid metal remains in its liquid state during package operation. The adhesive 152 also optionally serves to bond the thermoelectric cooler 30 to the molding material 56. The mixture 150 of gel and liquid metal also fills the interior grooves 60 disposed over the one or more semiconductor dies 11, 12, 13 to provide increased thermal contact area.

FIG. 4 also includes an Inset D which is the same as Inset C of FIG. 1. Inset D shows bottom views of the thermoelectric cooler 30 with three different pattern embodiments for the grooves 60. These patterns are merely nonlimiting illustrative examples.

The semiconductor package 10 of FIGS. 1 and 2 and the semiconductor package 100 of FIG. 4 each include the thermoelectric cooler 30 as a heat spreading lid disposed over the one or more semiconductor dies 11, 12, 13.

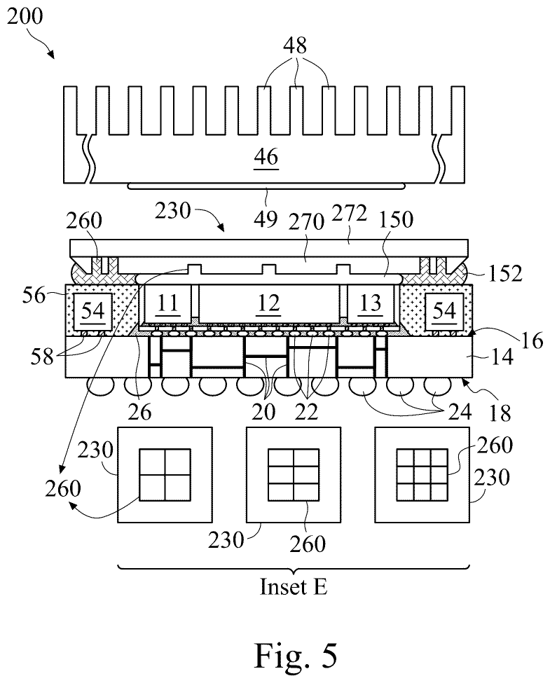

With reference now to FIG. 5, an exploded sectional view is shown of a semiconductor package 200 according to another embodiment, which differs from the semiconductor package 100 of FIG. 4 by relacing the thermoelectric cooler 30 of the semiconductor package 100 of FIG. 4 with a heat spreading lid 230 which comprises a metal, a single-crystal diamond, or a combination thereof. The semiconductor package 200 of FIG. 5 is otherwise similar to the semiconductor package 100 of FIG. 4, and also includes many components which are the same as already described for the semiconductor package 100 of FIG. 4, including: the one or more semiconductor dies 11, 12, 13; the interposer 14 with first and second principle surfaces 16 and 18 and electrical vias 20 passing therethrough; sets of bonding bumps 22 and 24 and underfill material 26 filling the space between the bonding bumps 22; the cold plate or heat sink 46 with optional thermal dissipation fins 48; and the stiffener ring 54 with optional pedestals or feet 58 and surrounding molding material 56.

The illustrative semiconductor package 200 of FIG. 5 is also similar to the illustrative semiconductor package 100 of FIG. 4 in that it includes thermally conductive material disposed between the one or more semiconductor dies 11, 12, 13 and the heat-spreading lid 230 comprising a metal, single-crystal diamond or combination thereof, with the thermally conductive material implemented as previously described with reference to FIG. 4 as mixture 150 of a gel and a liquid metal (e.g., gallium which has a melting point of about 30° C.). Analogously with the illustrative semiconductor package 100 of FIG. 4, the illustrative semiconductor package 200 of FIG. 5 includes adhesive 152 disposed on the periphery of the heat-spreading lid 230 comprising a metal, single-crystal diamond or combination thereof, e.g. on the molding 56 surrounding the stiffening ring 54. The adhesive 152 encircles and contains the mixture 150 of gel and liquid metal so that the liquefied metal (e.g., liquid gallium) does not flow and escape from the semiconductor package 200 at its operating temperature. Optional thermal interface material 49 also coats the opposite surface of the cold plate or heat sink 46 which contacts the heat-spreading lid 230 to provide improve thermal heat transfer from the heat-spreading lid 230 to the cold plate or heat sink 46.

The heat-spreading lid 230 comprising a metal, single-crystal diamond or combination thereof includes optional grooves 260 formed in the surface of the heat-spreading lid 230 facing the one or more semiconductor dies 11, 12, 13 and the stiffener ring 54. The adhesive 152 and mixture 150 of gel and liquid metal fills the grooves 260 of the heat-spreading lid 230. The grooves 260 can have various geometries, as diagrammatically shown in Inset E included in FIG. 5. Inset E shows bottom views of the heat-spreading lid 230 with three different pattern embodiments for the grooves 260. These patterns are merely nonlimiting illustrative examples.

As previously noted, the semiconductor package 200 shown in FIG. 5 includes the mixture 150 of gel and liquid metal as the thermally conductive material disposed between the one or more semiconductor dies 11, 12, 13 and the heat spreading lid 230. In a variant embodiment (not shown), the semiconductor package 200 of FIG. 5 with the heat-spreading lid 230 comprising a metal, single-crystal diamond or combination thereof could instead have thermally conductive material disposed between the one or more semiconductor dies 11, 12, 13 and the heat spreading lid 230 in the form of thermal insulating material 50 (by way of some nonlimiting illustrative examples, comprising indium, silver, copper, an indium alloy, a silver alloy, a copper alloy, or a solder material), as previously described with reference to FIGS. 1 and 2.

The thermoelectric cooler 30 of the semiconductor packages 10 and 100 of FIGS. 1 and 2 and FIG. 4, respectively, provides active cooling via the Peltier effect implemented by the thermoelectric cooler 30. As such, the thermoelectric cooler 30 is powered by the thermoelectric cooler power supply 44 and connecting wires 45 diagrammatically shown in FIGS. 1 and 4 (or alternative power connection if the power supply is integrated into the one or more semiconductor dies 11, 12, 13). In the embodiment of FIG. 5, on the other hand, the heat spreading lid 230 comprising a metal, a single-crystal diamond, or a combination thereof provides passive heat transfer from the one or more semiconductor dies 11, 12, 13 to the cold plate or heat sink 46. Hence, the heat spreading lid 230 of the semiconductor package 200 of FIG. 5 is not connected with an electric power supply. Rather, the heat spreading lid 230 has sufficiently high thermal conductivity to provide passive heat transfer from the one or more semiconductor dies 11, 12, 13 to the cold plate or heat sink 46. The heat spreading lid 230 may, in some nonlimiting illustrative examples, have a thickness of about 0.5 millimeter to about 3.0 millimeter, although a thickness outside of this range is contemplated.

In some embodiments, the heat spreading lid 230 of the semiconductor package 200 of FIG. 5 includes: a first layer 270 of a first material proximate to the one or more semiconductor dies 11, 12, 13; and a second layer 272 of a second material distal from the one or more semiconductor dies 11, 12, 13 and in contact with the cold plate or heat sink 46 (or with the thermal interface material 49 coating the cold plate or heat sink 46). The first material of the first layer 270 and the second material of the second layer 272 are different materials, and the first material has higher thermal conductivity than the second material (and, accordingly, the first layer 270 has higher thermal conductance than the second layer 272, at least for equal layer thicknesses). In some nonlimiting illustrative embodiments, the first layer 270 is a single-crystal diamond layer proximate to the one or more semiconductor dies 11, 12, 13, and the second layer 272 is a metal layer distal from the one or more semiconductor dies 11, 12, 13.

The various illustrative embodiments described above with reference to FIGS. 1-5 comprise a semiconductor package 10, 100, or 200 that includes: an interposer 14 having a first principle surface 16 and a second principle surface 18 opposite the first principle surface; one or more semiconductor dies 11, 12, 13 disposed on the first principle surface 16 of the interposer 14 and electrically connected with the second principle surface 18 of the interposer 14 by electrical vias 20 passing through the interposer 14; a heat spreading lid 30 or 230 disposed over the one or more semiconductor dies 11, 12, 13; and a thermally conductive material 50 or 150 disposed between the one or more semiconductor dies 11, 12, 13 and the heat spreading lid 30 or 230. The thermally conductive material 50 or 150 thermally couples the one or more semiconductor dies 11, 12, 13 and the heat spreading lid 30 or 230.

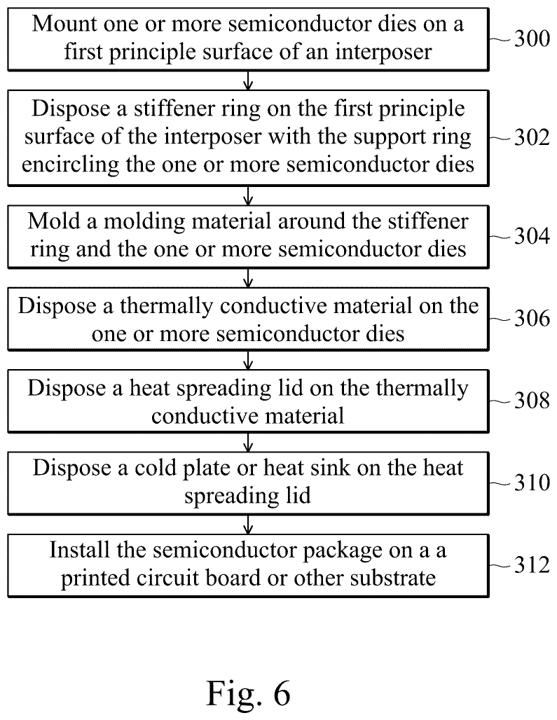

With reference now to FIG. 6, a method of assembling such a semiconductor package 10, 100, or 200 is described. In an operation 300, the one or more semiconductor dies 11, 12, 13 are mounted on the first principle surface 16 of the interposer 14. This may involve, by way of nonlimiting illustrative example, disposing the bonding bumps 22 on the one or more semiconductor dies 11, 12, 13, or on the first principle surface 16 of the interposer 14, and bonding the one or more semiconductor dies 11, 12, 13 to the first principle surface 16 of the interposer 14 via the bonding bumps 22, e.g., by application of heat to partially melt the bonding bumps 22 (or a solder coating disposed on the bonding bumps 22). The underfill material 26 may then be applied by capillary action or the like to fill the space between the bonding bumps 22. A curing process may optionally be applied at one or more stages of the operation 300. In an operation 302, the stiffener ring 54 is disposed on the first principle surface 16 of the interposer 14, encircling the one or more semiconductor dies 11, 12, 13. In an operation 304, the molding material 56 is molded around the stiffener ring 54 and the one or more semiconductor dies 11, 12, 13. It is noted that the operations 300, 302, and 304 may in general be performed various orders.

In an operation 306, the thermally conductive material 50 or 150 is disposed on the one or more semiconductor dies 11, 12, 13. In assembling the semiconductor packages 100 and 200 of FIGS. 4 and 5 in which the thermally conductive material is the mixture 150 of gel and liquid metal, the operation 306 may suitably also include disposing the adhesive 152 around the area of the mixture 150. Note that as the assembly is typically performed at room temperature, the liquid metal may be in solid form during assembly (e.g., gallium has a melting point of about 30° C., which is above room temperature); hence, the adhesive 152 may in general be disposed before or after the mixture 150 of gel and liquid metal. In an operation 308, the heat spreading lid 30 or 230 is disposed on the thermally conductive material 50 or 150. (In a variant embodiment, the operation 308 may be performed before the operation 306, with the operation 306 entailing injecting the thermally conductive material into a gap between the one or more semiconductor dies 11, 12, 13 and the heat spreading lid 30 or 230). In an operation 310, the cold plate or heat sink 46 is disposed on the heat spreading lid 30 or 230. The thermal interface material 49 may provide bonding of the cold plate or heat sink 46 to the heat spreading lid 30 or 230 sufficient to retain the former on the latter.

The operation 310 may, in some workflows, be considered to complete fabrication of the semiconductor package 10, 100, or 200. To deploy the semiconductor package 10, 100, or 200 in an electronic device or system, in an operation 312 the semiconductor package 10, 100, or 200 is installed on a printed circuit board or other substrate (not shown). This may entail disposing the bonding bumps 24 on the second principle surface 18 of the interposer 14 (or, alternatively the bonding bumps 24 may be disposed on the second principle surface 18 of the interposer 14 at an earlier stage of the semiconductor package assembly), and used to bond the semiconductor package 10, 100, or 200 to the printed circuit board or other substrate. This also implements electrical connection of the one or more semiconductor dies 11, 12, 13 to circuitry of the printed circuit board or other substrate by way of electrical connections provided by the electrical vias 20 of the interposer 14 and the bonding bumps 22 and 24.

Optionally, the operation 312 may further include securing the semiconductor package 10, 100, or 200 to the printed circuit board or other substrate using an external retention mechanism (not shown), such as a clamping mechanism. The clamping mechanism may, for example, clamp down on the cold plate or heat sink 46 to press the semiconductor package 10, 100, or 200 down onto the printed circuit board or other substrate. In other embodiments, it is contemplated for the cold plate or heat sink 46 to be a component of the clamping mechanism, so that the clamping mechanism includes the cold plate or heat sink 46 via which the clamping mechanism presses the cold plate or heat sink 46 against the heat-spreading lid 30 or 230 of the semiconductor package 10, 100, or 200.

It is to be appreciated that the semiconductor package assembly method described herein with reference to FIG. 6 is merely a nonlimiting illustrative example, and that the semiconductor package 10, 100, or 200 may be assembled in other ways, and/or with assembly operations performed in a different order.

In the following, some further embodiments are described.

In a nonlimiting illustrative embodiment, a semiconductor package includes: an interposer having a first principle surface and a second principle surface opposite the first principle surface; one or more semiconductor dies disposed on the first principle surface of the interposer and electrically connected with the second principle surface of the interposer by electrical vias passing through the interposer; a heat spreading lid disposed over the one or more semiconductor dies; and a thermally conductive material disposed between the one or more semiconductor dies and the heat spreading lid, the thermally conductive material thermally coupling the one or more semiconductor dies and the heat spreading lid. The heat spreading lid comprises a thermoelectric cooler, a metal, a single-crystal diamond, or a combination thereof.

In a nonlimiting illustrative embodiment, a method of assembling a semiconductor package includes: mounting one or more semiconductor dies on a first principle surface of an interposer with the one or more semiconductor dies electrically connected with a second principle surface of the interposer opposite from the first surface by way of electrical vias passing through the interposer; disposing a stiffener ring on the first principle surface of the interposer with the stiffener ring encircling the one or more semiconductor dies; molding a molding material around the stiffener ring and the one or more semiconductor dies; disposing a thermally conductive material on the one or more semiconductor dies; and disposing a heat spreading lid on the thermally conductive material.

In a nonlimiting illustrative embodiment, a semiconductor package includes: an interposer having a first principle surface and a second principle surface opposite the first principle surface; one or more semiconductor dies disposed on the first principle surface of the interposer and electrically connected with the second principle surface of the interposer by electrical vias passing through the interposer; a stiffener ring disposed on the first principle surface of the interposer and encircling the one or more semiconductor dies; a molding material molded around the stiffener ring and the one or more semiconductor dies; a thermally conductive material disposed on the one or more semiconductor dies; and a heat spreading lid disposed on the thermally conductive material. The heat spreading lid comprises a thermoelectric cooler, and/or the thermally conductive material comprises a mixture of a gel and a liquid metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
an interposer having a first principle surface and a second principle surface opposite the first principle surface;
one or more semiconductor dies disposed on the first principle surface of the interposer and electrically connected with the second principle surface of the interposer by electrical vias passing through the interposer;
a heat spreading lid disposed over the one or more semiconductor dies; and
a thermally conductive material disposed between the one or more semiconductor dies and the heat spreading lid, the thermally conductive material thermally coupling the one or more semiconductor dies and the heat spreading lid;
wherein the heat spreading lid comprises a thermoelectric cooler, a metal, a single-crystal diamond, or a combination thereof.

2. The semiconductor package of claim 1, wherein the heat spreading lid comprises a thermoelectric cooler.

3. The semiconductor package of claim 2, wherein the thermally conductive material comprises indium, silver, copper, an indium alloy, a silver alloy, a copper alloy, or a solder material.

4. The semiconductor package of claim 3, further comprising:
a metal coating disposed on a surface of the thermoelectric cooler in contact with the thermally conductive material.

5. The semiconductor package of claim 3, further comprising:
a stiffener ring disposed on the first principle surface of the interposer and encircling the one or more semiconductor dies; and
a molding material molded around the stiffener ring and the one or more semiconductor dies;
wherein the thermoelectric cooler has grooves formed in a surface thereof and the thermally conductive material fills the grooves of the thermoelectric cooler.

6. The semiconductor package of claim 2, wherein the thermally conductive material comprises a mixture of a gel and a liquid metal.

7. The semiconductor package of claim 6, wherein the liquid metal comprises gallium and the gel comprises a polymer.

8. The semiconductor package of claim 6, further comprising:
a stiffener ring disposed on the first principle surface of the interposer and encircling the one or more semiconductor dies;
a molding material molded around the stiffener ring and the one or more semiconductor dies; and
an adhesive disposed on a periphery of the thermoelectric cooler and containing the mixture of the gel and the liquid metal, the adhesive bonding the thermoelectric cooler to the molding material;
wherein a surface of the thermoelectric cooler has grooves and the adhesive fills the grooves.

9. The semiconductor package of claim 1, wherein the heat spreading lid comprises a metal, a single-crystal diamond, or a combination thereof.

10. The semiconductor package of claim 9, wherein the heat spreading lid comprises a single-crystal diamond layer proximate to the one or more semiconductor dies and a metal layer distal from the one or more semiconductor dies.

11. The semiconductor package of claim 9, wherein the heat spreading lid comprises a first layer of a first material proximate to the one or more semiconductor dies and a second layer of a second material distal from the one or more semiconductor dies, wherein the first material and the second material are different materials and wherein the first material has higher thermal conductivity than the second material.

12. The semiconductor package of claim 9, wherein the thermally conductive material comprises a mixture of a gel and a liquid metal.

13. The semiconductor package of claim 12, further comprising:
a stiffener ring disposed on the first principle surface of the interposer and encircling the one or more semiconductor dies;
a molding material molded around the stiffener ring and the one or more semiconductor dies; and
an adhesive disposed on a periphery of the thermoelectric cooler and containing the mixture of the gel and the liquid metal, the adhesive bonding the thermoelectric cooler to the molding material.

14. A method of assembling a semiconductor package, the method comprising:
mounting one or more semiconductor dies on a first principle surface of an interposer with the one or more semiconductor dies electrically connected with a second principle surface of the interposer opposite from the first surface by way of electrical vias passing through the interposer;
disposing a stiffener ring on the first principle surface of the interposer with the stiffener ring encircling the one or more semiconductor dies;
molding a molding material around the stiffener ring and the one or more semiconductor dies;
disposing a thermally conductive material on the one or more semiconductor dies; and
disposing a heat spreading lid on the thermally conductive material.

15. The method of claim 14, wherein the heat spreading lid comprises a thermoelectric cooler having grooves on a surface thereof, and the thermally conductive material fills the grooves.

16. The method of claim 14, wherein the thermally conductive material comprises a mixture of a gel and a liquid metal, and the method further comprises:
disposing an adhesive surrounding the mixture of the gel and the liquid metal;
wherein the adhesive fills grooves on a surface of the thermoelectric cooler contacting the adhesive and the mixture of the gel and the liquid metal.

17. The method of claim 14, wherein the heat spreading lid comprises a single-crystal diamond layer proximate to the one or more semiconductor dies and a metal layer distal from the one or more semiconductor dies, and the thermally conductive material comprises a mixture of a gel and a liquid metal.

18. A semiconductor package comprising:
an interposer having a first principle surface and a second principle surface opposite the first principle surface;
one or more semiconductor dies disposed on the first principle surface of the interposer and electrically connected with the second principle surface of the interposer by electrical vias passing through the interposer;
a stiffener ring disposed on the first principle surface of the interposer and encircling the one or more semiconductor dies;
a molding material molded around the stiffener ring and the one or more semiconductor dies;
a thermally conductive material disposed on the one or more semiconductor dies; and
a heat spreading lid disposed on the thermally conductive material;
wherein at least one of (i) the heat spreading lid comprises a thermoelectric cooler, and/or (ii) the thermally conductive material comprises a mixture of a gel and a liquid metal.

19. The semiconductor package of claim 18, wherein the heat spreading lid comprises a thermoelectric cooler.

20. The semiconductor package of claim 18, wherein the thermally conductive material comprises a mixture of a gel and a liquid metal, and the semiconductor package further comprises:
an adhesive surrounding the mixture of the gel and the liquid metal and sealing the mixture of the gel and the liquid metal in a sealed volume.
